(19) United States
(12) Patent Application Publication
(10) Pub. No.: US 2008/0265915 A1
(43) Pub. Date: Oct. 30, 2008

(54) METHOD OF DETECTING A NETWORK CABLING CHANGE

(75) Inventors: Charles F. Clark, Roseville, CA (US); Paul T. Congdon, Granite Bay, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: HEWLETT-PACKARD DEVELOPMENT COMPANY, L.P., Houston, TX (US)

(21) Appl. No.: 11/739,688

(22) Filed: Apr. 24, 2007

(51) Int. Cl. G01R 27/06; G01R 27/02

(52) U.S. Cl. 324/699; 324/693

(57) ABSTRACT

A system and method of detecting a network cabling change comprises measuring cable parameters of a cable to create a baseline signature of the cable and storing the baseline signature in a memory. The system and method is operable to detect a cable change based upon a comparison of the stored baseline signature and a subsequent cable measurement. A network device operable to perform the above method comprises a physical layer device that transmits signals into a coupled cable and receives return signals from the cable, a cable diagnostic module that measures cable parameters, a memory operable to store a baseline cable signature, and a controlling system that compares subsequently measured cable parameters to the baseline cable signatures to detect a cable change.

### BACKGROUND

Managing secure networks comprises managing the physical security of network cabling. In some instances, secure networks physically secure network cables to prevent unauthorized access to the network cables and, in turn, to the secure network.

A prior approach to providing physical security for network cabling includes running the cables through pressurized pipes and monitoring the pipes for any pressure changes. A change in pressure would indicate the possibility of an attempt to access the cabling inside the pipe. Depending upon the size and layout of a network's cabling, physical security of cables may not be feasible, and, even if feasible, may be prohibitively expensive.

### DESCRIPTION OF THE DRAWINGS

One or more embodiments are illustrated by way of example, and not by limitation, in the figures of the accompanying drawings wherein elements having the same reference numeral designations represent like elements throughout and wherein:

FIG. 1 is a block diagram of a network device operable to detect a change in cable characteristics of connected cables according to an embodiment;

FIG. 2 is a detailed block diagram of a network device according to an embodiment;

FIG. 3 is a flowchart illustrating a method according to an embodiment; and

FIG. 4 is a flowchart illustrating another method according to an embodiment.

### DETAILED DESCRIPTION

The apparatus and methods described herein utilize cable measurement techniques to monitor and report changes to a connected cable based upon a previously stored baseline signature of the cable. Furthermore, in the event that such changes were unauthorized, the collected data may be used to pinpoint each affected network device and cable. Still further, in some embodiments, a security policy prevents network traffic originating from a changed portion of the network to be forwarded though uncompromised portions of the network. Still other aspects comprise a user input device operable by authorized personnel to alter the security profile and update the baseline signature of the cable.

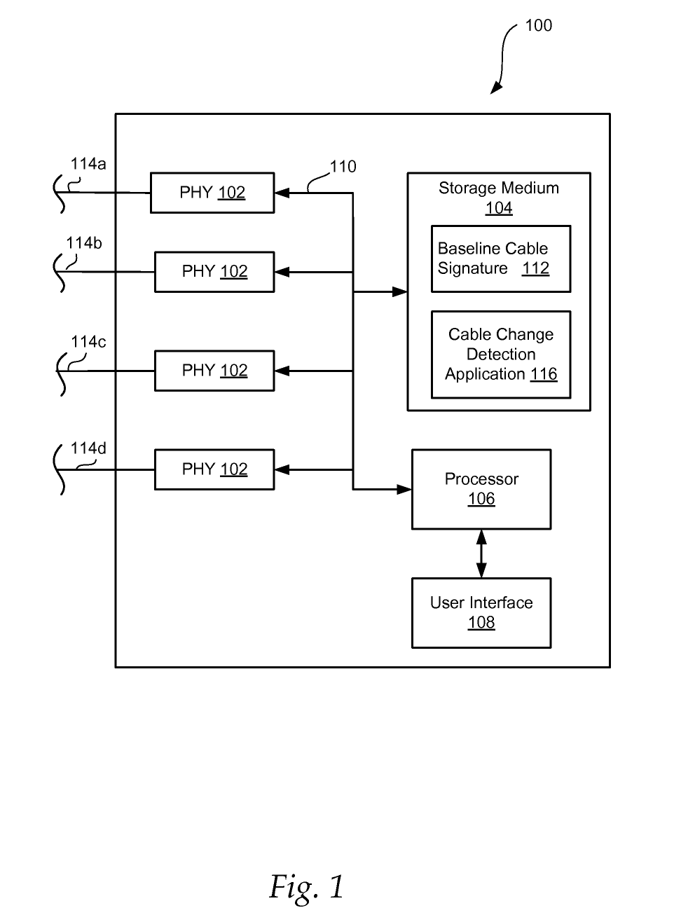

FIG. 1 illustrates a network device 100, e.g., a network router, Ethernet switch, bridging device, etc., according to an embodiment. Network device 100 is coupled to at least one cable of cables 114a-d via a physical layer device or line interface, i.e., PHY 102, which transmits and receives data to/from a corresponding cable of cables 114a-d. In addition, network device 100 comprises at least one processor 106, a user interface 108, and a storage medium 104 connected via a bus 110. In at least some embodiments, network device 100 comprises a physical layer device 102 for the cables 114a-d. In at least some embodiments, network device 100 comprises a physical layer device 102 for each cable of cables 114a-d. In at least some embodiments, network device 100 comprises one or more physical layer devices 102 corresponding to one or more cables of cables 114a-d.

The functions of methods described in connection with the embodiments disclosed herein may be embodied directly in hardware, in a set of executable instructions stored in one or more storage medium 104 executed by processor 106, or in a combination thereof. Storage medium 104 comprises a cable change detection application 116 that may comprise RAM memory, flash memory, ROM memory, PROM memory, EPROM memory, EEPROM memory, registers, hard disk, a removable disk, a CD-ROM, or another form of storage medium. Network device 100 comprises a bus 110 which couples storage medium 104 to processor 106 such that the processor 106 reads information from, and writes information to, the storage medium. In at least some embodiments, storage medium 104 is integral to processor 106. In some further embodiments, processor 106 and storage medium 104 may reside in an ASIC.

Each PHY 102 couples to one of cables 114a-d. Under control of processor 106, a PHY 102 performs cable diagnostics on a cable of cables 114a-d. The result of the diagnostics is compared with a stored baseline signature 112 for the cable of cables 114a-d connected to PHY 102. Non-limiting, baseline signature 112 may be stored in memory 104 collocated with cable change detection application 116 or may reside in any memory device 104 accessible by processor 106 or PHY 102. Furthermore, baseline signature 112 may be stored in a network storage device remotely accessible by network device 100. In some embodiments, baseline signature 112 is generated from data received from PHY 102 at the time of cable installation. In some embodiments, baseline signature 112 for one or more of cables 114a-d may be calculated and stored upon receipt of a command from an authorized user via, for example, user interface 108.

In some embodiments, user interface 108 comprises a command line interface (CLI) that allows an authorized user to interact with cable change detection application 116. In other embodiments, a security token, to be further described below, may be inserted into network device 100 to add an additional layer of security that prevents unauthorized users from updating the baseline cable signature 112 in addition to modifying any security profile regarding operation of the cable change detection method described herein. In still other embodiments, an authorized user, operating at a centralized management station, may interface with cable change detection apparatus 116, via a mechanism such as simple network management protocol (SNMP). Such a remote access capability allows an authorized user to remotely issue a command to apparatus 116 to calculate and store the baseline signature 112 for one or more cable 114.

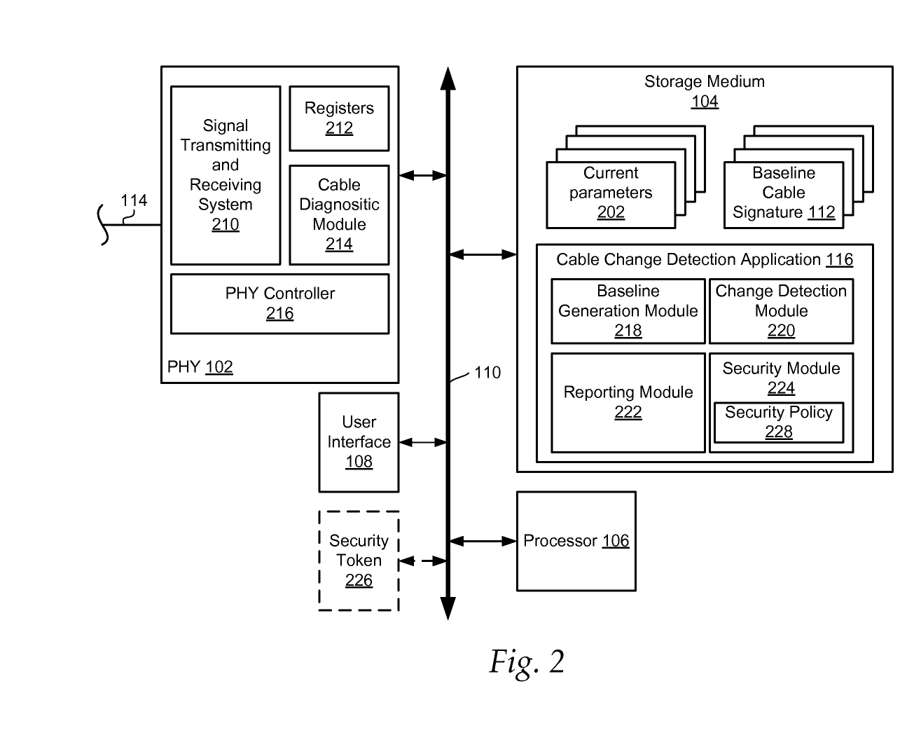

Referring to FIG. 2, each PHY 102 comprises a signal transmitting and receiving system 210, registers 212, a cable diagnostic module 214, and a PHY controller 216. For simplicity and ease of discussion, FIG. 2 depicts only a single PHY 102. Cable diagnostic module 214 detects network cabling installation conditions, such as cable length, opens, shorts, coupling between pairs, and termination status. In some embodiments, signal transmitting and receiving system 210, under control of PHY controller 216, generates and transmits a signal along cable 114. A return or reflected signal is then received at signal transmitting and receiving system 210 and is processed by cable diagnostic module 214 to determine characteristics, i.e., cable parameters, such as cable length, crosstalk, pair skew, and impedance. Depending upon the specific diagnostic method employed by PHY 102 and the characteristics of the connected network cabling, PHY 102 may require a configured transmission link between two network devices to be down before performing diagnostics. In other embodiments, cable diagnostics provide real-time continuous dynamic monitoring of the link quality.

In some embodiments, cable diagnostic module 214 utilizes time-domain reflectometry (TDR) by relying on the electromagnetic properties of waves along a transmission line. A pulse of known amplitude is transmitted into the cable through signal transmitting and receiving system 210 and a reflection occurs unless the impedance of the load exactly matches the characteristic impedance of the cable. The type and location of the fault is determined by cable diagnostic module 214 measuring the response. Furthermore, a cable length or the distance to a cabling fault is determined from the time difference between the transmitted and reflected pulse.

TDR is an effective and accurate method for determining failure modes during cable installation. However, because the signaling method is different from normal data traffic over the network device 100, TDR may require the link to be taken down to diagnose a failure.

In other embodiments, cable diagnostic module 214 may use an alternative to TDR to perform cable diagnostics, including, but not limited to using signal processing parameters to recover data and operating in parallel with normal data traffic to provide continuous real-time monitoring of signal conditions and channel performance that may indicate an unauthorized cable change. Excessive attenuation, frequency offset, cross-talk, or noise is detected when the signal processing capabilities of the signal transmitting and receiving system 210 are operating outside the normal and expected range for a particular cable length, as stored in baseline 112.

The same signal processing parameters also provide an estimate of cable length. Using this approach, the measurement can be made without interrupting normal data flow.

In some embodiments, PHY 102 measures cable characteristics or monitors changes in the signal transmitting and receiving system parameters for each cable 114a-d to determine real time cable parameters that are stored in memory registers 212. Non-limiting, memory registers 212 comprise registers for cable length, crosstalk, pair skew, and impedance and PHY 102 triggers an interrupt or otherwise notifies processor 106 when new measurements are available. In other embodiments, PHY 102 has direct access to baseline cable signature 112 and notifies processor 106 of a change in cable characteristics.

The cable change detection capability described herein is controlled by the cable change detection application software module 116 in storage medium 104 and, in at least some embodiments, comprises one or more sub modules, e.g., security module 224, baseline generation module 218, change detection module 220, and reporting module 222.

Security module 224 is operable to maintain at least one security policy 228 that determines, for example, when a baseline cable signature 112 is updated, when to notify a system administrator of a detected change in cable characteristics, what, if any, routing changes to implement upon detection of a cable change, and by what means to interface with an authorized user. Furthermore, in some embodiments, security profile 228 comprises a predetermined set of thresholds, e.g., a one foot margin for cable length, which allows for small variations in detected differences between the baseline signature 112 and logged current parameters 202.

Furthermore, security module 224 may require a different password or access method for the cable change detection application 116 than for other features of device 100. For example, security module 224 may require the insertion of a security token 226, such as a preconfigured USB flash memory drive that may store cryptographic keys, such as a digital signature, or biometric data, such as a fingerprint.

Baseline generation module 218 is operable to create and store a new baseline signature 112 for one or more cables 114a-d based upon a specific event, e.g., the installation of a new cable 114, an authorized maintenance operation, etc. For example, an authorized user may, via the user interface 108, initiate an ad hoc baseline generation for one or more cables 114a-d. In other embodiments, baseline generation module 218 may automatically generate a new baseline signature 112 upon bringing up a link for the first time after cable installation.

Change detection module 220 is operable to collect cable measurements stored in registers 212 of PHY 102 and store the data as current parameters 202 in storage medium 104. In addition to the cable data, change detection module 220 is operable to store a date, time and cable identifier as part of current parameters 202. In some embodiments, change detection module 220 is operable to continually read registers 212. In other embodiments, PHY controller 216 is operable to interrupt processor 106 when new measurements are available. In still other embodiments, the specific baseline cable signature 112 for each cable is downloaded to the PHY 102 where controller 216 is responsible for detecting a change in cable characteristics and notifying processor 106 of the event and the measurements logged.

Reporting module 222 is operable to report the event and the logged measurements to an authorized user either via user interface 108 and/or a network connection to a remote location performing centralized network maintenance. In one embodiment, the incident report comprises the baseline signature 112, one or more of the current parameters 202 comprising the date and time of the incident, and cable identification data.

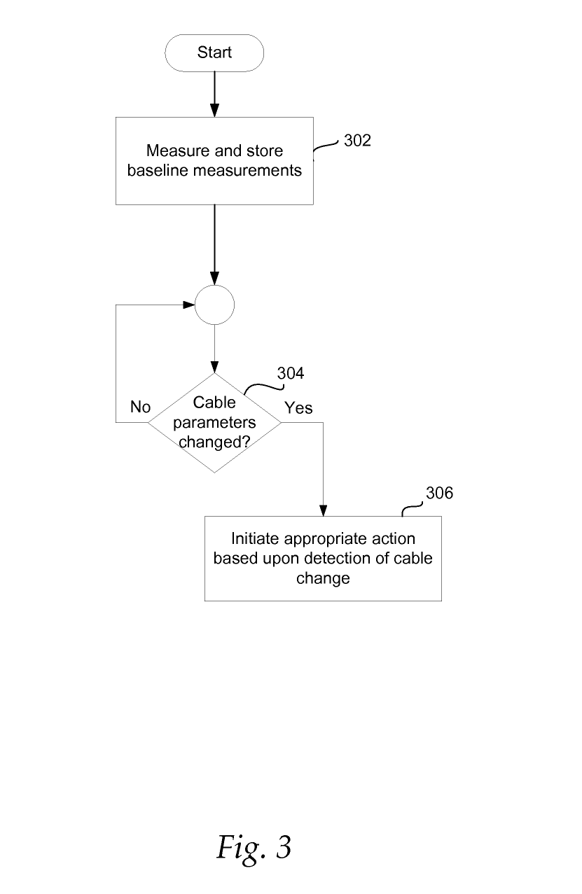

FIG. 3 illustrates a flowchart of an embodiment performing the methods described herein and begins with measuring and storing a baseline signature 112 of each connected cable 114a-d. For example, baseline generation module 218 operating in conjunction with each PHY 102 measures or calculates cable parameters based upon the specific cable diagnostic technique employed by the PHY 102, reading PHY memory registers 212, and storing a baseline signature 112.

A subsequent test 304 determines if a cable has been changed. Cable test 302 is performed by PHY 102 in a manner similar to calculating the baseline signature 112. However, in some embodiments, the time of the testing is based on status of the link supported by the cable. For example, in some embodiments, the testing is performed only when the link carried by the cable to be tested is down. In such an embodiment, testing is performed continually while the link is down and is stopped once the link is brought back up. Link status may be determined by PHY 102, or by processor 106. In other embodiments, cable testing is performed continuously, regardless of the state of the link, in parallel with the normal data routing function of device 100. In this mode, PHY controller 216 may operate independent of processor 106, reporting new measurements on an interrupt or polled basis. Further still, an authorized user may initiate an ad hoc cable test request.

In other embodiments, PHY 102 compares registers 212 against baseline signature values 112. If no changes were detected, or if predetermined thresholds were not met, network device 100 continues normal operations until a subsequent test 304 is performed.

On the other hand, when the stored baseline signature 112 and the current parameters are different, an appropriate action 306 is performed based upon the currently executing security profile 228. For example, a maintenance operation may be in progress wherein an authorized user has entered an appropriate command via the user interface 108, or has inserted security token 226 to modify the existing security policy. Under these circumstances, the security profile may indicate that the measurements be logged, but not immediately reported/transmitted to a system administrator. If, however, a change is detected and the security policy 228 indicates that an unauthorized cable change may have occurred, security policy 228 may indicate that the incident be reported to a remote console, e.g., a network management center, along with the log information. In one embodiment, the incident report comprises the logged cable parameters 202, the baseline signature 112, the date and time of the incident, and cable identification data.

Furthermore, using routing tables currently existing in network devices, security policy 228 is operable to isolate the suspect cable to prevent traffic originating from a changed portion of the network from being forwarded though uncompromised portions of the network. In addition, traffic originating from uncompromised cables may similarly be rerouted so as to avoid a suspect cable.

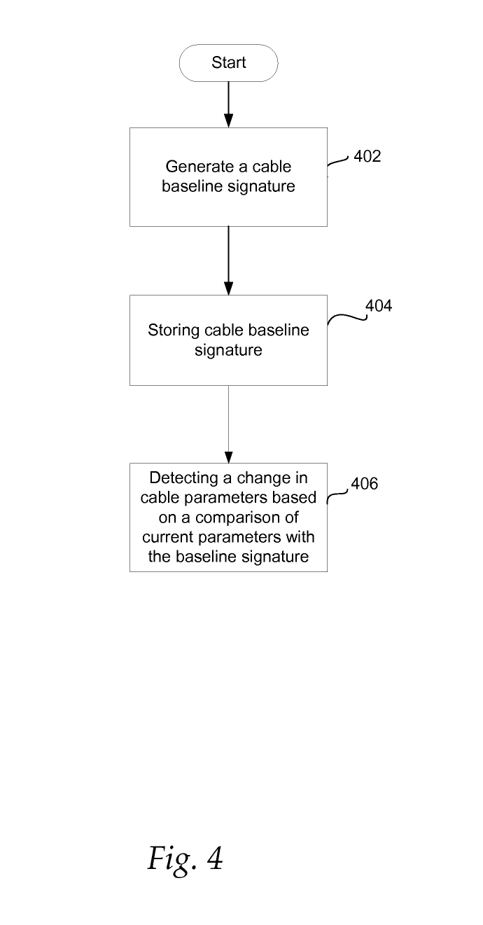

FIG. 4 illustrates a flowchart of an embodiment of a method of detecting a network cabling change, and starts with a baseline signature generation functionality 402 that generates a baseline signature 112 of at least one cable 114 based on measuring one or more cable parameters of the at least one cable 114.

A baseline signature storing functionality 404 is then executed to store the baseline signature 112 in a memory 104.

Cable signature change detection functionality 406 is then operable to detect a change in the one or more cable parameters based upon a comparison of the stored baseline signature 112 and current parameters 202 of the at least one cable 114.

The functions of a method or algorithm described in connection with the embodiments disclosed herein may be embodied directly in hardware, in a software module executed by a processor, or in a combination of the two. A software module may reside in RAM memory, flash memory, ROM memory, PROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC.

What is claimed is:

1. A method of detecting a network cabling change, comprising:
generating a baseline signature of one or more cable parameters of at least one cable based on measuring the one or more cable parameters of the at least one cable;
storing the baseline signature in a memory; and
detecting a change in the one or more cable parameters based upon a comparison of the stored baseline signature and a subsequent measurement of the one or more cable parameters of the at least one cable.

2. The method of claim 1, wherein the generating a baseline signature comprises performing time domain reflectometry (TDR) on the at least one cable.

3. The method of claim 1, wherein generating a baseline signature comprises determining at least one of a measure of cable length, a measure of crosstalk between conductors, a measure of pair skew between conductors, and a measure of impedance for the at least one cable.

4. The method of claim 1, further comprising logging the detected change in cable parameters.

5. The method of claim 1, further comprising enforcing a security policy upon the detection of a change in at least one of the one or more cable parameters.

6. The method of claim 5, wherein enforcing a security policy comprises generating a notification of a detected change in at least one of the one or more cable parameters.

7. The method of claim 6, further comprising forwarding an event report of the detected change in at least one of the one or more cable parameters.

8. The method of claim 5, further comprising changing the security policy upon identification of an authorized user.

9. The method of claim 1, wherein subsequent cable measurements comprises measuring cable parameters based upon a link status of the cable.

10. The method of claim 1, wherein subsequent cable measurements comprise continually checking at least one of the one or more cable parameters.

11. The method of claim 1, further comprising updating the baseline signature of the at least one cable upon user authorization.

12. The method of claim 1, wherein a security policy prevents network traffic originating from a changed portion of a connected network to be forwarded though uncompromised portions of the network.

13. A computer program product, comprising a computer-readable medium comprising:
a first set of codes for creating a baseline signature of one or more cable parameters of at least one cable;
a second set of codes for detecting a change in at least one of the one or more cable parameters based upon a comparison of the baseline signature with a subsequent cable measurement.

14. A network device operable to detect a change to at least one cable connecting the network device to a network, comprising:
a physical layer device arranged to transmit one or more signals into a coupled cable and receives one or more return signals from the cable;
a cable diagnostic module arranged to measure one or more cable parameters;
a memory operable to store a baseline signature of at least one of the one or more cable parameters of the cable; and
a controlling system arranged to compare the baseline signature of the cable to a subsequent measurement of at least one of the one or more cable parameters to detect whether a change in the cable has occurred.

15. The network device of claim 14, wherein the cable diagnostic module comprises a time domain reflectometry (TDR) system that receives one or more signals from the physical layer device to determine a set of one or more cable parameters.

16. The network device of claim 14, wherein the baseline signature comprises a measurement comprising at least one of a length of the cable, a measure of crosstalk between conductors, a measure of pair skew between conductors, and a measure of cable impedance.

17. The network device of claim 14, further comprising a security module comprising at least one security policy wherein the security module is operable to control the detection of unauthorized cable changes.

18. The network device of claim 17, further comprising a security token operable to change the security policy.

19. The network device of claim 17, wherein the security policy comprises a predetermined set of threshold values for the measured cable parameters.

20. The network device of claim 17, wherein the security policy prevents network traffic originating from a changed portion of the network to be forwarded though uncompromised portions of the network.
